(19) United States
(12) Patent Application Publication
(10) Pub. No.: US 2022/0386423 A1
(43) Pub. Date: Dec. 1, 2022

(54) INDUCTION HEATING DEVICE

(71) Applicant: LG Electronics Inc., Seoul (KR)

(72) Inventors: Sihoon Jeong, Seoul (KR); Ho Yong Jang, Seoul (KR); Bada Yoon, Seoul (KR); Gwangrok Kim, Seoul (KR)

(21) Appl. No.: 17/752,009

(22) Filed: May 24, 2022

(30) Foreign Application Priority Data
May 25, 2021 (KR) 10-2021-0067105

(51) Int. Cl. H05B 6/06; H05B 6/04; H05B 6/44; G01R 19/25

(52) U.S. Cl. CPC H05B 6/062; H05B 6/04; H05B 6/44; G01R 19/25

(57) ABSTRACT

An induction heating device according to and embodiment may include a working coil; an inverter circuit comprising a plurality of switching elements and configured to supply currents to the working coil; a rectifier circuit configured to rectify the voltage supplied from an external power source; a smoothing circuit configured smooth the voltage output from the rectifier circuit; a drive circuit configured to supply a switching signal to each of the switching circuits; a controller configured to supply a control signal for outputting the switching signal to the drive circuit; a shunt resistor connected between the smoothing circuit and the inverter circuit; an input current sensing circuit configured to sense an input current value of the inverter circuit based on a current flowing through the shunt resistor; and a resonance current sensing circuit a resonance current value of the working coil based on the current flowing through the shunt resistor

### CROSS-REFERENCE TO RELATED APPLICATION

This application claims priority to and the benefit of Korean Patent Application No. 10-2021-0067105, filed in Korea on May 25, 2021, which is incorporated herein by reference in its entirety.

### BACKGROUND

### 1. Field

An induction heating device is disclosed herein.

### 2. Background

An induction heating device is a device, which includes mechanism that heats a container by generating an eddy current in a metal container, using a magnetic field generated around a working coil. When the induction heating device is driven, an alternating current may be applied to the working coil. Accordingly, an induction magnetic field may be generated around the working coil disposed in the induction heating device. When a magnetic force line of the induced magnetic field generated in this way passes through the bottom of the container having a metal component placed on the working coil, an eddy current may be generated inside the bottom of the container. When the eddy current generated in this way flows through the container, the container itself may be heated.

FIG. 1 illustrates a circuit view of an induction heating device according to the prior art.

The induction heating device 7 in FIG. 1 may include two working coils 712 and 714, that is, a first working coil 712 and a second working coil 714. The first working coil 712 and the second working coil 714 may be provided in respective positions corresponding to a first heating area and a second heating area.

The induction heating device 7 according to the prior art may include a rectifier circuit 702, a smoothing circuit 704, a first inverter circuit 706 and a second inverter circuit 708.

The rectifier circuit 702 may include a plurality of diodes and rectify the voltage supplied from an external power source 700. The smoothing circuit 704 may include a first inductor L1 and a first DC link capacitor C1. The smoothing circuit 704 may smooth the voltage output from the rectifier circuit 702 and output a DC voltage.

The first inverter circuit 706 may be a half-bridge inverter circuit including two switching elements SW1 and SW2 and two capacitor elements C1 and C2. The second inverter circuit 708 may be a half-bridge inverter circuit including two switching elements SW3 and SW4 and two capacitor elements C3 and C4.

When the switching elements are supplied based on the control of a controller, the first inverter circuit 706 and the second inverter circuit 708 may receive current through the rectifier circuit 702 and the smoothing circuit 704, and then convert the input currents into alternating current to supply the converted currents to the first working coil 712 and the second working coil 714, respectively.

Meanwhile, the induction heating device 7 according to the prior art may include a first CT sensor CT1 for sensing the current input to the first working coil 712 and the second working coil 714 (i.e., the input current). Specifically, the induction heating device 7 according to the prior art may include one CT (Current Transformer) sensor configured to sense the input currents to the plurality of the inverter circuits.

In addition, the induction heating device 7 according to the prior art may include a second CT sensor CT2 and a third CT sensor CT3 configured to sense the current flowing through the first working coil 712 and the second working coil 714, that is, the resonance current, when the first working coil 712 and the second working coil 714 are driven.

FIG. 2 is a graph showing the drive timing of the first working coil 712 and the second working coil 714 provided in the induction heating device according to the prior art.

FIG. 2 shows a graph of change in output power values of the first working coil 712 and change in output power values of the second working coil 714, when the first working coil 712 and the second working coil 714 are driven simultaneously.

As shown in FIG. 1, the conventional induction heating device 7 may include one CT sensor, that is, the first CT sensor CT1 for sensing the input currents of the first working coil 712 and the second working coil 714. Accordingly, when the first working coil 712 and the second working coil 714 are driven, the input currents of the first working coil 712 and the second working coil 714 may be alternately sensed to accurately sense the input currents of the inverter circuits.

As one example, as shown in FIG. 2, there are time sections T1, T2, T3 and T4 in which the output power values of the first working coil 712 and the second working coil 714 become ‘zero’ based on a predetermined period according to the prior art. In the prior art, each working coil is periodically turned on and off, instead of continuously driven.

The controller may sense the input current value of the second working coil 714 for each section T1 and T2 in which the output power value of the first working coil 712 becomes 0 (zero) by using the first CT sensor CT1. Specifically, the controller may obtain an accurate input current value by measuring an input current value of the other inverter circuit, unless one of the working coils is driven.

According to the prior art, the input current values of the plurality of the inverter circuits have to be sensed by using one CT sensor. Thus, there is a disadvantage that a very complicated current measurement method is required to obtain the accurate input values as described with reference to FIG. 2.

In addition, according to the prior art, each of the working coils has to be periodically turned on and off and is not continuously driven, according to the method for measuring the currents described in reference with FIG. 2. Since noise is induced by the periodic turn on and off of the working coils, there could be another disadvantage that the user is likely to feel uncomfortable.

FIG. 3 is a graph showing a waveform of a resonance current obtained by the CT sensor provided in the induction heating device according to the prior art.

According to the prior art, when the first working coil 712 and the second working coil 714 are simultaneously driven, the controller may obtain the resonance current values of the first working coil 712 and the second working coil 714, respectively, using the second CT sensor CT2 and the third CT sensor CT3. FIG. 3 shows the waveform of the resonance current sensed by each of the second CT sensor CT2 and the third CT sensor CT3, when the first working coil 712 and the second working coil 714 are simultaneously driven.

In general, the working coil provided in the conventional heating apparatus is driven in a relatively high frequency band (e.g., 20 kHz to 60 kHz). Accordingly, when the first working coil 712 and the second working coil 714 are simultaneously driven, the driving of one working coil could affect the driving of the other working coil because of the high frequency band. When the resonance current value of one working coil is sensed during the simultaneous driving of the first working coil 712 and the second working coil 714, noise 730 due to the driving of the other working coil may be included in the waveform of the resonance current as shown in FIG. 3.

In addition, the resonance current value of each working coil shown in FIG. 3 may include a positive value and a negative value. However, in the conventional induction heating device according to the prior art, only a positive value may be measured by using the second CT sensor CT2 and the third CT sensor CT3 but a negative value may not be measured disadvantageously.

The prior art may have a problem in that the accurate resonance current value cannot be obtained using the second CT sensor CT2 or the third CT sensor CT3. Accordingly, the controller of the induction heating device according to the prior art may use only some (e.g., peak values) of the resonance current values sensed by the second CT sensor CT2 or the third CT sensor CT3 to control the induction heating device.

FIG. 4 shows a waveform of a resonance current that is sensed when heating a non-magnetic container and a magnetic container, using the induction heating device according to the prior art.

FIG. 4 shows a graph 741 showing a waveform of a resonance current sensed when heating a non-magnetic container through the induction heating device and a graph 742 showing a waveform of a resonance current sensed when heating a magnetic container through the induction heating device.

As shown in FIG. 4, the waveform of the resonance current varies based on the property of the container or vessel heated by using the induction heating device. As mentioned above, the resonance current values sensed by the CT sensors according to the prior art may include noise values. Furthermore, negative current values cannot be sensed. Accordingly, when using the CT sensor according to the prior art, it is impossible to accurately sense the resonance current value of each working coil when heating the containers having different property.

Meanwhile, the CT sensor used to sense the input current resonance current is a sensor configured to generate an alternating current, which is proportional to the current sensed in a primary coil, in a secondary coil based on the principle of a transformer. The CT sensor has a structure including a primary coil and a secondary coil. The CT sensor having the mentioned-structure has high unit cost. However, according to the prior art, as the number of the working coils provided in the induction heating device increases, the number of the CT sensors also increases, so that the manufacturing cost of the induction heating device increases.

### BRIEF DESCRIPTION OF THE DRAWINGS

Embodiments will be described in detail with reference to the following drawings in which like reference numerals refer to like elements, and wherein:

FIG. 1 is a circuit view of an induction heating device according to the prior art;

FIG. 2 is a graph showing the driving timing of a first working coil and the drive timing of a second working coil provided in the induction heating device according to the prior art;

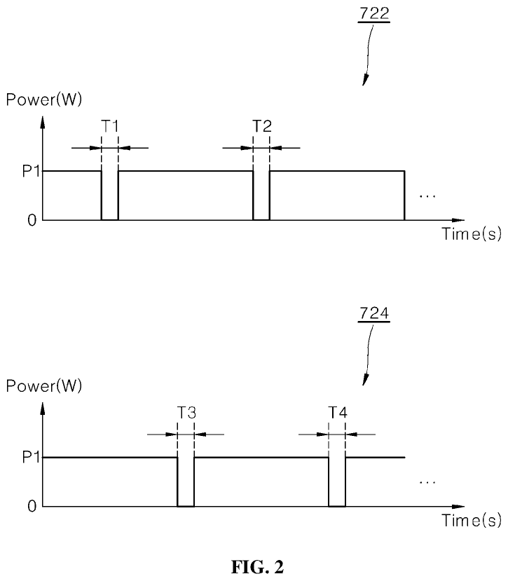

FIG. 3 is a graph showing a waveform of a resonance current obtained by a CT sensor provided in the induction heating device according to the prior art;

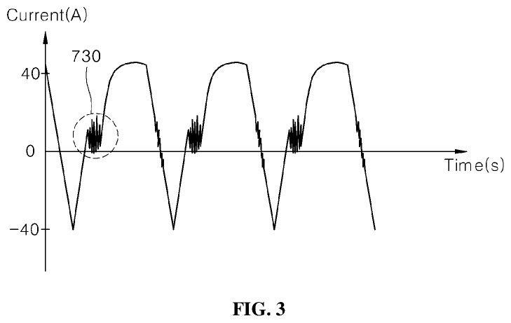

FIG. 4 shows a waveform of a resonance current that is sensed when heating a non-magnetic container and a magnetic container, using the induction heating device according to the prior art;

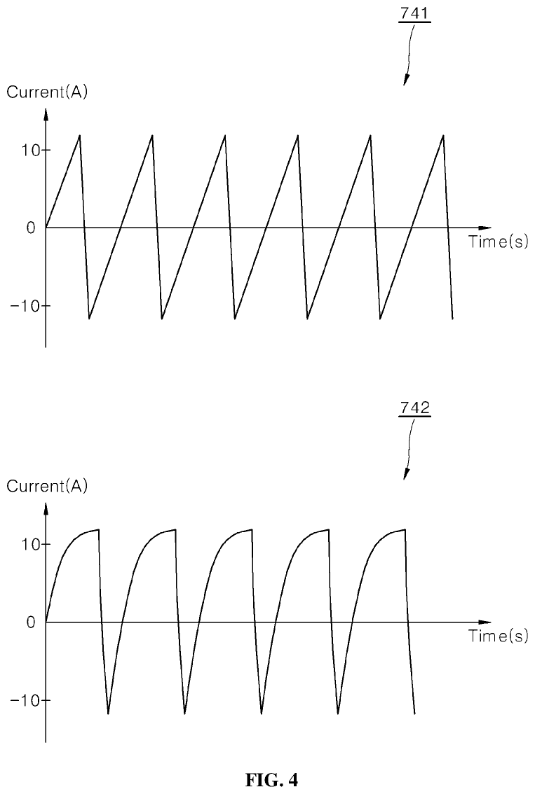

FIG. 5 is an exploded perspective view of an induction heating device according to an embodiment of the present disclosure;

FIG. 6 is a block diagram of an induction heating device of an embodiment of the present disclosure;

FIG. 7 is a circuit view of an input current sensing circuit or a resonance current sensing circuit provided in an induction heating device according to an embodiment of the present disclosure;

FIG. 8 is a graph showing an output power value of a working coil based on a power level input when heating a magnetic container and a non-magnetic container using the induction heating device according to the prior art; and

FIG. 9 is a graph showing an output power value of a working coil based on a power level input when heating a magnetic container and a non-magnetic container using an induction heating device according to an embodiment of the present disclosure.

### DETAILED DESCRIPTION

The above-described aspects, features and advantages are specifically described hereunder with reference to the accompanying drawings such that one having ordinary skill in the art to which the present disclosure pertains can easily implement the technical spirit of the disclosure. In the disclosure, detailed descriptions of known technologies in relation to the disclosure are omitted if they are deemed to make the gist of the disclosure unnecessarily vague. Below, preferred embodiments according to the disclosure are specifically described with reference to the accompanying drawings. In the drawings, identical reference numerals can denote identical or similar components.

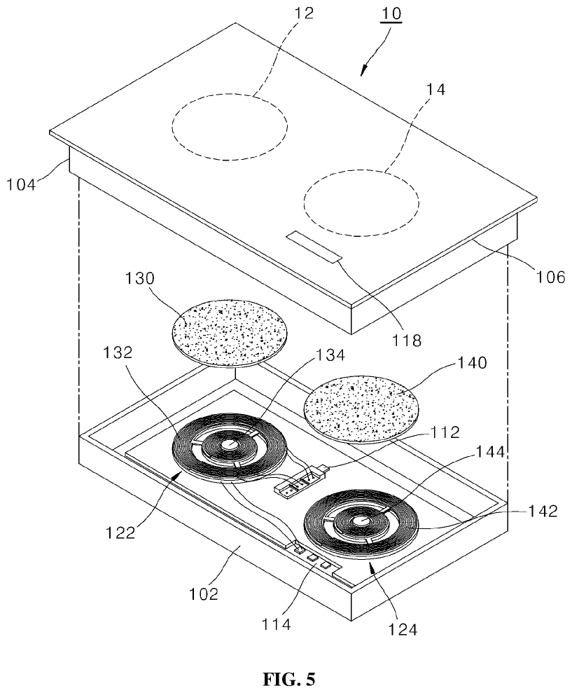

FIG. 5 is an exploded perspective view of an induction heating device according to an embodiment of the present disclosure.

Referring to FIG. 5, the induction heating device 10 may include a case 102 defining a main body, and a cover plate 104 coupled to the case 102 and sealing or covering the case 102.

The cover plate 104 may be coupled to an upper surface of the case 102 to close the space formed in the case 102 from the outside. The cover plate 104 may include a top plate 106 on which an object to be heated (i.e., a container for cooking food) is placed. The top plate 106 may be made of a tempered glass material such as ceramic glass, but is not limited thereto. The material of the top plate 106 may vary according to embodiments.

A first heating area 12 and a second heating area 14 corresponding to working coil assemblies 122 and 124, respectively, may be formed in or on the top plate 106. Lines or figures corresponding to the heating areas 12 and 14 may be printed or displayed on the top plate 106 in order for a user to clearly recognize the positions of the heating areas 12 and 14.

The case 102 may have a hexahedral shape with an open top. However, the shape of the case 102 is not limited and can have other shapes.

The working coil assembly 122 and 124 for heating a container or vessel may be disposed in the space formed inside the case 102. The number of working coil assemblies 122 and 124 is not limited. Examplary, there are two working coil assemblies 122 and 124. However, there might be only one or three or more working coil assemblies inside the case 102.

In addition, an interface unit 114 may be provided inside the case 102. The interface unit 114 may have functions to adjust or set a power level of each of the heating areas 12 and 14 and/or to display related information of the induction heating device 10. The interface unit 114 may be a touch panel that is capable of both inputting information and displaying information by touch, but the interface unit 114 may have a different structure, e.g., a separate input button and a display being located at a another place.

A manipulation region 118 may be formed in a position corresponding to the interface unit 114 in the top plate 106. For user manipulation, characters or images may be printed on the manipulation region 118. The user may perform a desired operation by touching a specific point of the manipulation region 118 with reference to the characters or images pre-printed on the manipulation region 118. In addition, the information output by the interface unit 114 may displayed through the manipulation region 118.

The user may set and adjust the power level of each heating area 12 and 14 through the interface unit 114. The power level may be indicated by a number (e.g., 1, 2, 3, . . . and 9) on the manipulation region 118. When the power level for each heating area 12 and 14 is set, the required power value and the heating frequency of the working coil assemblies 122, 124 responding to the respective heating areas 12 and 14 may be determined. A controller 2 (not shown in FIG. 5) may be provided to drive each of the working coils 132, 142 or the working coil assemblies 122, 124 so that the actual output power value can match the required power value set by the user based on the determined heating frequency.

Inside the case 102 there may be further provided a power source part 112 for supplying power to the first working coil assembly 122, the second working assembly 124 and the interface unit 114 and/or other electrical components.

In the embodiment of FIG. 5, two working coil assemblies (i.e., the first working coil assembly 122 and the second working coil assembly 124) are disposed inside the case 102. However, three or more working coil assemblies may be provided in the case 102 according to some embodiments.

Each working coil assembly 122 and 124 may include a working coil 132, 142 configured to induce a magnetic field using a high frequency alternating current supplied by the power source part 112. An insulating sheet may be provided to protect the coil 132, 142 from heat generated by the container. For example, the first working assembly 122 shown in FIG. 5 may include a first working coil 132 for heating the container put in the first heating area 12 and a first insulating sheet 130. The second working assembly 124 may include a second working coil 142 and a second insulating sheet 140. The insulating sheet may be omitted and/or may not be provided according to embodiments.

In addition, a temperature sensor may be provided at the center of each working coil 132 and 142. For example, a temperature sensor 134 may be provided in the center of the first working coil 132 and a second temperature sensor 144 may be provided in the center of the second working coil 142 as shown in FIG. 5. The temperature sensor may measure the temperature of the container put in each heating area.

In one embodiment of the present disclosure, the temperature sensor may be a thermistor temperature sensor having a variable resistance of which a resistance value changes according to the temperature of the container, but is not limited thereto.

In the embodiment, the temperature sensor may output a sensing voltage corresponding to the temperature of the container. The sensing voltage output from the temperature sensor may be transmitted to a controller 2.

The controller 2 may check the temperature of the container based on the magnitude of the sensing voltage output from the temperature sensor 134, 144. When the temperature of the container corresponds to a preset reference value or more, the controller 2 may perform an overheat protection operation of lowering the actual power value of the working coil 132, 142 or stopping the driving of the working coil 132, 142.

Although not shown in FIG. 5, a circuit board may be disposed in the space formed inside the case 102, wherein a plurality of circuits or elements including the controller 2 may be placed on such circuit board.

The controller 2 may perform a heating operation by driving each of the working coils 132 and 142 based on the user's heating start command input through the interface unit 114. When the user inputs a heating terminating command through the interface unit 114, the controller 2 may stop the driving of each of the working coils 132 and 142 to terminate the heating operation.

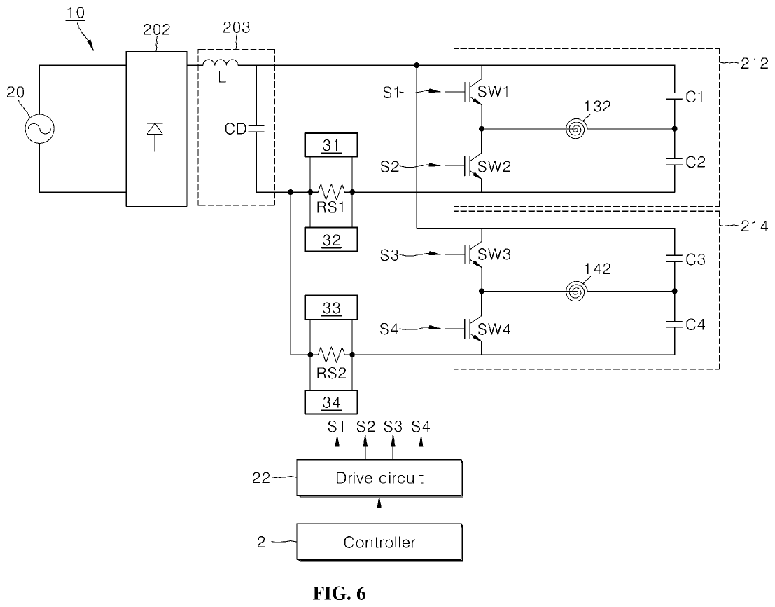

FIG. 6 is a block diagram of an induction heating device according to one embodiment of the present disclosure.

Referring to FIG. 6, the induction heating device 10 according to the embodiment may include a rectifier circuit (or a rectifier) 202, a smoothing circuit 203, a first inverter circuit (or a first inverter) 212, a first working coil 132, a second inverter circuit (or a second inverter) 214, a second working coil 142, a controller 2 and a drive circuit (or a driver) 22.

The rectifier circuit 202 may include a plurality of diode elements. In one embodiment of the present disclosure, the rectifier circuit 202 may be a bridge diode circuit. However, it may be another type circuit depending on embodiments. The rectifier 202 may rectify the AC input voltage supplied from the external power source 20 to output a voltage having a pulsating waveform.

The smoothing circuit 203 may smooth the voltage rectified by the rectifier circuit 202 to output a DC link voltage. The smoothing circuit 203 may include an inductor L and a DC link capacitor CD.

The first inverter circuit 212 may include a first switching element SW1, a second switching element SW2, a first capacitor C1 and a second capacitor C2. The first switching element SW1 and the second switching element SW2 may be connected in series with each other. The first capacitor C1 and the second capacitor C2 may be connected in series with each other. The first working coil 132 may be connected between the connection point of the first switching element SW1 and the second switching element SW2 and the connection point of the first capacitor C1 and the second capacitor C2. The first inverter circuit 212 may convert the current output from the smoothing circuit 203 into an AC current, and supply the converted AC current to the first working coil 132.

The second inverter circuit 214 may include a third switching element SW3, a fourth switching element SW4, a third capacitor C3 and a fourth capacitor C4. The third switching element SW3 and the fourth switching element SW4 may be connected in series with each other. The third capacitor C3 and the fourth capacitor C4 may be connected in series with each other. The second working coil 142 may be connected between the connection point of the third switching element SW3 and the fourth switching element SW4 and the connection point of the third capacitor C3 and the fourth capacitor C4. The second inverter circuit 214 may convert the current output from the smoothing circuit 203 into an AC current, and supply the converted AC current to the second working coil 142.

The DC link voltage input to the inverter circuits 212 and 214 may be converted into the alternating current by the turn-on and turn-off (i.e., the switching operation) of the switching elements SW1, SW2, SW3 and SW4 of the inverter circuits 212 and 214. The alternating currents converted by the inverter circuits 212 and 214 may be supplied to the working coils 132 and 142, respectively. When the alternating current is supplied to the working coils 132 and 142, there may be a resonance phenomenon in the working coils and an eddy current may flow to heat the container.

In one embodiment of the present disclosure, the first switching element SW1 and the second switching element SW2 may be alternately turned on and off. The third switching element SW3 and the fourth switching element SW4 may be alternately turned on and off.

The controller 2 may output a control signal for controlling the drive circuit 22. The drive circuit 22 may supply switching signals S1, S2, S3 and S4 to the switching elements SW1, SW2, SW3 and SW4 based on the control signal supplied by the controller 2, respectively. In the present disclosure, the first switching signal S1, the second switching signal S2, the third switching signal S3 and the fourth switching S4 may be pulse width modulation (PWM) signals each having a predetermined duty cycle.

When the AC current output from the inverter circuit 212 and 214 is supplied to the working coil 132 and 142, the working coil 132 and 142 may be driven. While eddy current flows through the container put on the working coil 132 and 142, with the driving of the working coil 132 and 142, the container may be heated. The amount of thermal energy supplied to the container may vary based on the amount of power actually generated by the driving of the working coil, that is, the actual output power value of the working coil.

When the user changes a current state of the induction heating device 10 into a power-on state by manipulating the input interface 114 via the manipulation region 118, the external power source device 20 may supply power to the induction heating device 10 and the induction heating device 10 may enter or start a driving standby state. Hence, the user may place a vessel or container on the first heating area 12 and/or the second heating area 14 and set a power value required for the heating area 12 and/or the second heating area 14 to start a heating start command. Once the user inputs the heating start command, the controller 2 may determine a required power value of each working coil 132 and 142 corresponding to the power level set by the user.

The controller 2 having received the heating start command may determine a frequency corresponding to the required power value of each working coil 132 and 142, namely, a heating frequency, and supply a control signal corresponding to the determined heating frequency to the drive circuit 22. Accordingly, the switching signals S1, S2, S2 and S4 may be output from the drive circuit 22 and the working coils 132 and 142 may be driven as the switching signals S1, S2, S3 and S4 are input to the switching elements SW1, SW2, SW3 and SW4, respectively. Hence, the working coils 132 and 142 may be driven so that the eddy current can flow through the container to be heated.

In this implementation, the controller 2 may determine the heating frequency that is the frequency corresponding to the power level set by the user. As one example, the user sets a power level for the heating area. Then, the controller 2 may gradually lower the driving frequency of the inverter circuit 212 and 214, until the output power value of the working coil 132 and 142 becomes equal to the required power value corresponding to the power level set by the user in a state where the driving frequency of the inverter circuit 212 and 214 is set to a preset reference frequency. The controller 2 may determine the frequency when the output power value of the working coil 132 and 142 becomes equal to the required power value to be the heating frequency.

The controller 2 may supply a control signal corresponding to the determined heating frequency to the drive circuit 22. The drive circuit 22 may output switching signals S1, S2, S3 and S4 having a predetermined duty ratio corresponding to the heating frequency determined by the controller based on the control signal output by the controller 2. While the switching elements SW1, SW2, SW3 and SW3 are alternately turned on and off by the input of the switching signals S1, S2, S3 and S4, the AC current may be supplied to the working coil 132 and 142. Accordingly, the container placed on the heating area 14 may be heated.

Meanwhile, the induction heating device 10 according to one embodiment may include shunt resistors RS1 and RS2. In the example of FIG. 6, the first shunt resistance RS1 may be connected between the smoothing circuit 203 and the first inverter circuit 212. The second shunt resistor RS2 may be connected between the smoothing circuit 203 and the second inverter circuit 214.

The induction heating device 10 according to one embodiment may include input current sensing circuits 31 and 33 configured to sense the currents input to the inverter circuits 212 and 214 based on the currents flowing to the shunt resistors RS1 and RS2, namely, the input currents of the inverter circuits 212 and 214, respectively.

In the example of FIG. 6, the first input current sensing circuit 31 may sense the current input to the first inverter circuit 212, namely, the input current of the first inverter circuit 212. The second input current sensing circuit 33 may sense the current input to the second inverter circuit 214, namely, the input current of the second inverter circuit 214.

The induction heating device 10 according to one embodiment may further include resonance current sensing circuits 32 and 34 configured to sense the current flowing through the working coils 132 and 142 based on the current flowing in the shunt resistors RS1 and RS2, namely, the resonance current of the working coils 132 and 142.

In the example of FIG. 6, the first resonance current sensing circuit 32 may sense the current flowing in the first working coil 132, namely, the resonance current of the first working coil 132. The second resonance current sensing circuit 34 may sense the current flowing in the second working coil 142, namely, the resonance current of the second working coil 142.

The controller 2 may determine the input current value of the inverter circuit 212 and 214 based on the current value output from the input current sensing circuit 31 and 33. In addition, the controller 2 may determine the resonance current value of the working coil 132 and 142 based on the current value output from the resonance current sensing circuit 32 and 34.

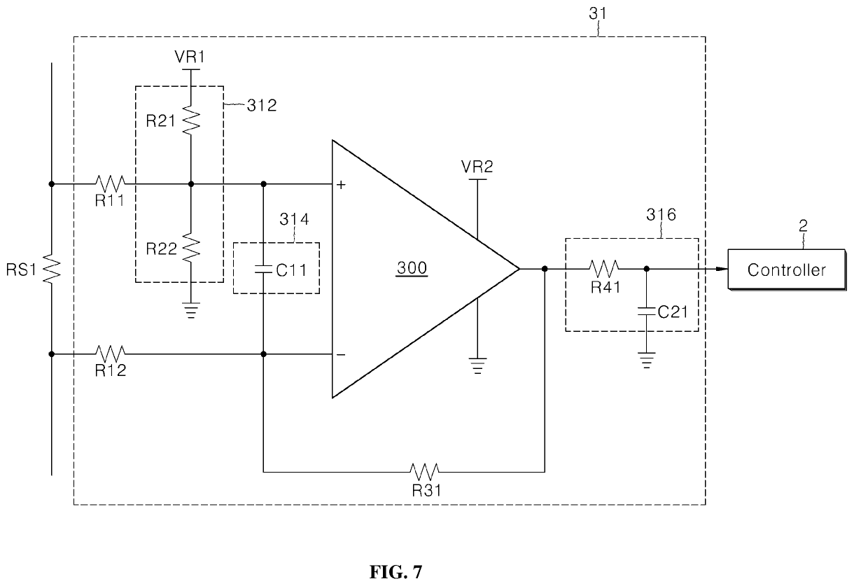

FIG. 7 is a circuit view of an input current sensing circuit 31, 33 or a resonance current sensing circuit 32, 34 provided in an induction heating device 10 according to the embodiment of the present disclosure.

In FIG. 7, only the circuit view of the first input current sensing circuit 31 is shown. However, the second input current sensing circuit 33, the first resonance current sensing circuit 32, and the second resonance current sensing circuit 34 shown in FIG. 6 may have the same circuits as the first input current sensing circuit 31 shown in FIG. 7.

Referring to FIG. 7, the first current sensing circuit 31 may include an off-set voltage supply circuit 312, a noise filter circuit 314, a comparator 300 and a low pass filter 316.

The offset voltage supply circuit 312 may include a first voltage divider resistor R21 and a second voltage divider R22 that are connected in series with each other. The offset voltage supply circuit 312 may supply an offset voltage to the comparator 300 based on a first reference voltage VR1. The magnitude of the current flowing through the first shunt resistor RS1, namely, the current value may be a positive value or a negative value. When the offset voltage is supplied by the offset voltage supply circuit 312, the current value output from the comparator 300 may always become a positive value.

To set or adapt an input current, resistors R11 and R12 may be provided in front of the offset voltage supply circuit 312.

The magnitude of the offset voltage supplied by the offset voltage supply circuit 312 may vary based on resistance values of the first voltage divider resistor R21 and the second voltage divider resistor R22. The magnitude of the offset voltage supplied by the offset voltage supply circuit 312 may be set so that the current value output from the comparator 300 may be always a positive value

The noise filter circuit 314 may include a capacitor C11. The noise filter circuit 314 may serve to remove the noise generated in the process of sensing a current value flowing through the first shunt resistor RS1. For example, when the first working coil 132 and the second working coil 142 are being driven simultaneously, the noise signal generated by the second working coil 142 may be filtered by the noise filter circuit 314, so that the magnitude of the first shunt resistor RS1 may be more accurately sensed.

The comparator 300 may output a digital value corresponding to the magnitude of the current flowing through the first shunt resistor RS1. As mentioned above, the comparator 300 may be set to always output a positive value by the offset voltage supplied by an offset voltage supply circuit 312.

The low-pass filter circuit 316 may be an RC filter circuit including a resistor R41 and a capacitor C21. The low-pass filter circuit 316 may filter a signal having a predetermined reference frequency or more.

The filtering range of the low-pass filter circuit 316 may vary based on a resistance value of the resistor R41 and a capacitance value of the capacitor C21.

In the example of the present disclosure, a first low-pass filter circuit 316 provided in the input current sensing circuit 31 and 33 may pass a signal having a predetermined reference frequency or less (e.g., 20 Hz or 120 Hz). Accordingly, the input current sensing circuit 31 and 33 may sense only a current component corresponding to the input current among the current components flowing through the shunt resistors RS1 and RS2 to output an input current value.

The controller 2 may determine the magnitude of the input current input to the inverter circuit 212 and 214 based on the current values output from the input current sensing circuit 31 and 33.

In one example of the present disclosure, the controller 2 may calculate an average value of current values output from the input current sensing circuit 31 and 33, and determine the calculated average value as the input current value of the inverter circuit 212 and 214.

In addition, a second low-pass filter circuit provided in the resonance current sensing circuit 32 and 34 may pass a signal having a predetermined reference frequency or less (e.g., 100 kHz). Accordingly, the resonance current sensing circuit 32 and 34 may sense only a current component corresponding to the resonance current among the current components flowing through the shunt resistors RS1 and RS2 to output a resonance current value.

The controller 2 may determine the magnitude of the resonance current flowing through the working coil 132 and 142 based on the current value output from the resonance current sensing circuit 32 and 34. In one example of the present disclosure, the controller 2 may determine the current value output from the resonance current sensing circuit 32 and 34 to be the resonance current value of the working coil 132 and 142.

In implementations, a first reference frequency and a second reference frequency may vary according to embodiments of the present disclosure. Also, the resistance value of the resistor R41 and the capacitance value of the capacitor C21 for determining the first reference frequency and the second reference frequency may be set to be variable according to each embodiment.

As mentioned above, the induction heating device 10 may sense the input current value and the resonance current value based on the magnitude of the current flowing through the shunt resistors RS1 and RS2 connected between the smoothing circuit 203 and the inverter circuits 212 and 214.

Unlike the prior art, the induction heating device according to one embodiment of the present disclosure may separately include input current sensing circuits corresponding to respective inverter circuits. Accordingly, the induction heating device may efficiently and easily sense the input current value, without complicated controlling methods for sensing the input current value.

So, according to the invention a shunt resistor RS1 and RS2 is placed between the smoothing circuit 203 and the inverter circuits 212, 214, respectively.

Thus, the input current sensing circuits 31 and 33 and the resonance current sensing circuits 32 and 34 can be placed between the smoothing circuit 203 and the inverter circuits 212, 214, respectively and measure the input current supplied to the inverter circuits 212, 214.

In particular, the input current sensing circuits 31 and 33 and the resonance current sensing circuits 32 and 34 are placed in parallel to the shunt resistors RS1 and RS2, respectively. That means the input current sensing circuit 31 and the resonance current sensing circuit 32 are connected in parallel to the shunt resistor RS1 of the first inverter circuit 212.

Furthermore, the input current sensing circuit 33 and the resonance current sensing circuit 34 are connected in parallel to the shunt resistor RS2 of the second inverter circuit 214.

Each of the input current sensing circuits 31 and 33 and the resonance current sensing circuits 32 and 34 may include a noise filter circuit 314. Accordingly, when the plural working coils are driving at the same time, the noise signal generated by the driving of the other working coil may be removed and the input current value or the resonance current value may be sensed more accurately.

In this embodiment, due to the supply of the offset voltage, the input current value or the resonance current value may be always output as a positive value. Accordingly, it may be possible to completely restore the input current or the resonance current, and also it may be possible to obtain the more accurate input current value or resonance current value, so that more precise control of the induction heating device can become possible by using the input current value or the resonance current value.

In addition, even if the property of the container heated by the working coil area changes, it may be always possible to accurately sense the input current value or the resonance current value based on the digital value output from the input current sensing circuit or the resonance current sensing circuit.

The input current sensing circuit or the resonance current sensing circuit according to the embodiment of the present disclosure may be configured of a low-cost circuit including a resistor, a capacitor and a comparator, so that there may be an advantage in that the manufacturing cost of the induction heating device may be lower than that of the conventionally used CT sensor.

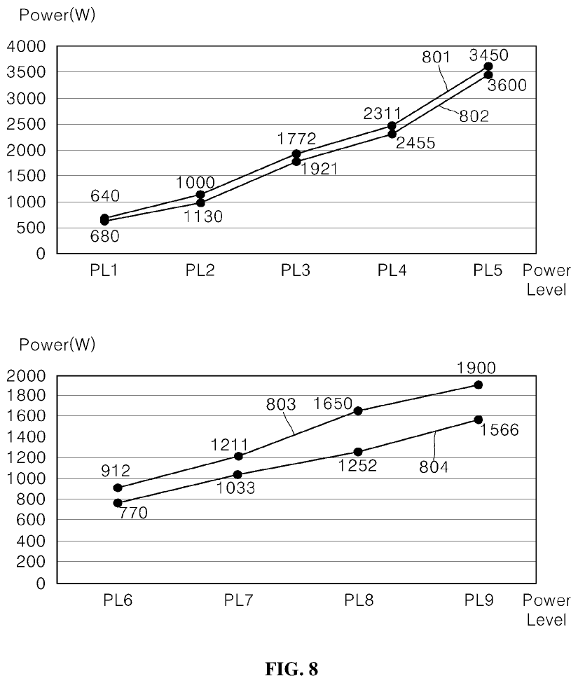

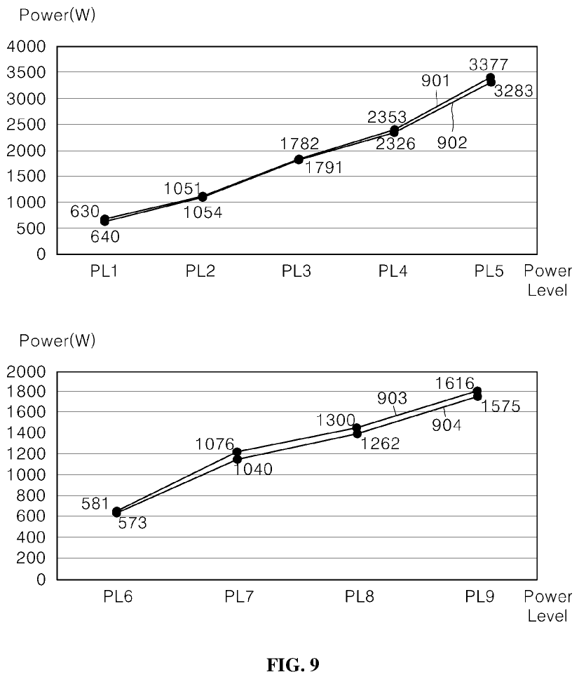

FIG. 8 is a graph showing an output power value of the working coil based on a power level input when the conventional heating apparatus according to the prior art heats a magnetic and non-magnetic container. FIG. 9 a graph showing an output power value of the working coil based on a power level input when the heating apparatus according to the embodiment of the present disclosure heats a magnetic and non-magnetic container.

FIG. 8 includes a graph 801 showing the output power value of the working coil calculated by the controller based on the input current value sensed when the conventional induction heating device heats the magnetic container and a graph 802 showing the output power value of the working coil actually measured by an auxiliary measuring device.

In addition, FIG. 8 includes a graph 803 showing the output power value of the working coil calculated by the controller based on the input current value sensed when the conventional induction heating device heats the non-magnetic container and a graph 804 showing the output power value of the working coil actually measured by the auxiliary measuring device.

As shown in FIG. 8, there is a difference between the output power value of the working coil calculated by the controller based on the input current value sensed when the container is heated and that of the working coil measured by the auxiliary measuring device. Especially, as shown in the graph 803 and the graph 804, when the non-magnetic container is heated through the working coil, the difference between the output power value of the working coil calculated by the controller based on the input current value and the output power value of the working coil actually measured through the auxiliary measuring device may become larger.

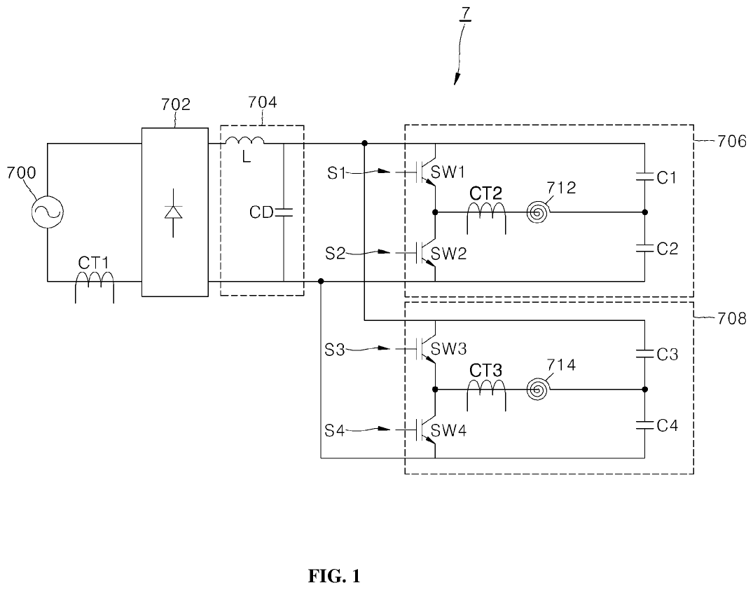

This means that the input current value sensed based according to the prior art, e.g. by a current transformer as shown in FIG. 1, is inaccurate compared to the actual input current value. Furthermore, as shown in FIG. 8, the accuracy of sensing the input current value also depends on the property of the container change and is further lowered.

Meanwhile, FIG. 9 includes a graph 901 showing the output power value of the working coil calculated by the controller based on the input current value sensed when the induction heating device according to one embodiment of the present disclosure heats the magnetic container. Also, FIG. 9 includes a graph 902 showing the output power value of the working coil actually measured by the auxiliary measuring device.

In addition, FIG. 9 includes a graph 903 showing the output power value of the working coil calculated by the controller based on the input current value sensed when the induction heating device according to one embodiment of the present disclosure heats the non-magnetic container. Also, FIG. 9 includes a graph 904 showing the output power value of the working coil actually measured by the auxiliary measuring device.

Referring to FIG. 9, the difference between the output power value of the working coil calculated by the controller based on the input current value and the output power value of the working coil actually measured through the auxiliary measuring device may get reduced, compared to the prior art. This means that the sensing accuracy of the input current value measured by the controller is increased, compared to the prior art.

As shown in FIG. 9, the induction heating device according to the embodiment of the present disclosure may always accurately sense the input current value regardless of the property of the container.

One object of the present disclosure is to provide an induction heating device that may easily sense an input current value and a resonance current value of an inverter circuit, without using a complicated sensing method.

Another object of the present disclosure is to provide an induction heating device that may accurately sense an input current value and a resonance value of an inverter circuit, when a plurality of working coils are simultaneously driven.

Another object of the present disclosure is to provide an induction heating device that may accurately sense an input current value and a resonance current value of an inverter circuit regardless of a property of a container to be heated.

Another object of the present disclosure is to provide an induction heating device that may lower the manufacturing cost, compared to the prior art.

Aspects according to the present disclosure are not limited to the above ones, and other aspects and advantages that are not mentioned above can be clearly understood from the following description and can be more clearly understood from the embodiments set forth herein.

The object is solved by the features of the independent claim. Preferred embodiments are given in the dependent claims.

Embodiments of the present disclosure may provide an induction heating device including a working coil disposed in a position corresponding to a heating area; an inverter circuit comprising a plurality of switching elements and configured to supply currents to the working coil; a rectifier circuit configured to rectify the voltage supplied from an external power source; a smoothing circuit configured smooth the voltage output from the rectifier circuit; a drive circuit configured to supply a switching signal to each of the switching circuits; a controller configured to supply a control signal for outputting the switching signal to the drive circuit; a shunt resistor connected between the smoothing circuit and the inverter circuit; an current sensing circuit configured to sense an input current value of the inverter circuit based on a current flowing through the shunt resistor and to sense a resonance current value of the working coil based on the current flowing through the shunt resistor.

In one or more embodiments, the current sensing circuit may comprise an input current sensing circuit configured to sense an input current value of the inverter circuit based on a current flowing through the shunt resistor; and a resonance current sensing circuit configured to sense a resonance current value of the working coil based on the current flowing through the shunt resistor.

In one or more embodiments, the input current sensing circuit may be is connected in parallel to the shunt resistor.

In one or more embodiments, the resonance current sensing circuit may be connected in parallel the shunt resistor.

In one or more embodiments, the input current sensing circuit and the resonance current sensing circuit have the same components.

In one or more embodiments, the input current sensing circuit and the resonance current sensing circuit may differ in the frequency of the output current.

Embodiments of the present disclosure may provide an induction heating device including a working coil disposed in a position corresponding to a heating area; an inverter circuit comprising a plurality of switching elements and configured to supply currents to the working coil; a rectifier circuit configured to rectify the voltage supplied from an external power source; a smoothing circuit configured smooth the voltage output from the rectifier circuit; a drive circuit configured to supply a switching signal to each of the switching circuits; a controller configured to supply a control signal for outputting the switching signal to the drive circuit; a shunt resistor connected between the smoothing circuit and the inverter circuit; an input current sensing circuit configured to sense an input current value of the inverter circuit based on a current flowing through the shunt resistor; and a resonance current sensing circuit configured to sense a resonance current value of the working coil based on the current flowing through the shunt resistor.

The current sensing circuit may include offset voltage supply circuit; and a comparator configured to output a digital value corresponding to the magnitude of the current flowing through the shunt resistor.

The current sensing circuit may include a noise filter circuit,

The input current sensing circuit may include offset voltage supply circuit; a noise filter circuit; a comparator configured to output a digital value corresponding to the magnitude of the current flowing through the shunt resistor; and a first low-pass filter circuit configured to pass a signal having a preset first frequency or less.

The resonance current sensing circuit may include an offset voltage supply circuit; a noise filter circuit; a comparator configured to output a digital value corresponding to the magnitude of the current flowing through the shunt resistor; and a second low-pass filter circuit configured to pass a signal having a preset second frequency or less.

The first low-pass filter circuit or the second low-pass filter circuit may be a RF filter circuit comprising a resistor element having a predetermined resistance value and a capacitor element having a predetermined capacitance value.

The controller may determine an average value of the current values output from the input current sensing circuit as the input current value of the inverter circuit.

The controller may determine the current value output from the resonance current sensing circuit as the resonance current value of the working coil.

The input current sensing circuit and the resonance current sensing circuit sense may be configured to sense current signals having different frequencies.

The current values output from the input current sensing circuit and the resonance sensing circuit may be positive values.

According to embodiments, the induction heating device is capable of easily sensing an input current value and a resonance current value of an inverter circuit, without using a complicated sensing method.

According to embodiments, the induction heating device is capable of accurately sensing an input current value and a resonance value of an inverter circuit, when a plurality of working coils are simultaneously driven.

According to embodiments, the induction heating device is capable of accurately sensing an input current value and a resonance current value of an inverter circuit regardless of property of a container to be heated.

According to embodiments, the manufacturing cost of the induction heating device can be lowered, compared to the prior art.

The embodiments are described above with reference to a number of illustrative embodiments thereof. However, the present disclosure is not intended to limit the embodiments and drawings set forth herein, and numerous other modifications and embodiments can be devised by one skilled in the art. Further, the effects and predictable effects based on the configurations in the disclosure are to be included within the range of the disclosure though not explicitly described in the description of the embodiments.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section could be termed a second element, component, region, layer or section without departing from the teachings of the present invention.

Spatially relative terms, such as “lower” and “upper”, for example, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An induction heating device comprising:
a working coil disposed to correspond to a heating area;
an inverter including a plurality of switching elements and configured to provide current to the working coil;
a rectifier circuit configured to rectify voltage from an external power source;
a smoothing circuit configured to smooth the voltage from the rectifier circuit;
a drive circuit configured to provide a switching signal to each of the switching elements;
a controller configured to provide a control signal to the drive circuit for outputting the switching signal;
a shunt resistor to connect between the smoothing circuit and the inverter;
an input current sensing device configured to sense an input current value of the inverter based on a current flowing through the shunt resistor; and
a resonance current sensing device configured to sense a resonance current value of the working coil based on the current flowing through the shunt resistor.

2. The induction heating device of claim 1, wherein the input current sensing device comprises:
an offset voltage supply circuit;
a noise filter;
a comparator configured to output a digital value corresponding to magnitude of the current flowing through the shunt resistor; and
a first low-pass filter configured to output a signal having a preset first frequency or less.

3. The induction heating device of claim 2, wherein the first low-pass filter is a RF filter that includes a resistor element having a predetermined resistance value and a capacitor element having a predetermined capacitance value.

4. The induction heating device of claim 2, wherein the resonance current sensing device comprises:
an offset voltage supply circuit;
a noise filter;
a comparator configured to output a digital value corresponding to magnitude of the current flowing through the shunt resistor; and
a second low-pass filter configured to output a signal having a preset second frequency or less.

5. The induction heating device of claim 4, wherein the second low-pass filter is a RF filter that includes a resistor element having a predetermined resistance value and a capacitor element having a predetermined capacitance value.

6. The induction heating device of claim 1, wherein the controller is configured to determine an average value of the current values output from the input current sensing device as the input current value of the inverter.

7. The induction heating device of claim 1, wherein the controller is configured to determine the current value output from the resonance current sensing device as the resonance current value of the working coil.

8. The induction heating device of claim 1, wherein the input current sensing device and the resonance current sensing device are configured to sense current signals having different frequencies.

9. The induction heating device of claim 1, wherein the current values output from the input current sensing device and the resonance current sensing device are positive values.

10. An induction heating device comprising:
a first working coil disposed to correspond to a first heating area;
a second working coil disposed to correspond to a second heating area;
a first inverter having a first plurality of switching elements and a second inverter having a second plurality of switching elements, the first inverter configured to provide current for driving the first working coil and the second inverter configured to provide current for driving the second working coil;
a drive circuit configured to provide a switching signal to each of the switching elements;
a controller configured to provide a control signal to the drive circuit for outputting the switching signal;
a first shunt resistor to connect to the first inverter;
a second shunt resistor to connect to the second inverter;
a first input current sensing device configured to sense an input current value of the first inverter based on a current flowing through the first shunt resistor;
a second input current sensing device configured to sense an input current value of the second inverter based on a current flowing through the second shunt resistor;
a first resonance current sensing device configured to sense a resonance current value of the first working coil based on the current flowing through the first shunt resistor; and
a second resonance current sensing device configured to sense a resonance current value of the second working coil based on the current flowing through the second shunt resistor.

11. The induction heating device of claim 10, further comprising:
a rectifier circuit configured to rectify voltage from an external power source; and
a smoothing circuit configured to smooth the voltage from the rectifier circuit.

12. The induction heating device of claim 11, wherein the first shunt resistor to connect between the smoothing circuit and the first inverter, and the second shunt resistor to connect between the smoothing circuit and the second inverter.

13. The induction heating device of claim 10, wherein the first input current sensing device or the second input current sensing device comprises:
an offset voltage supply circuit;
a noise filter;
a comparator configured to output a digital value corresponding to magnitude of the current flowing through the first shunt resistor; and
a first low-pass filter configured to output a signal having a preset first frequency or less.

14. The induction heating device of claim 10, wherein the first resonance current sensing device or the second resonance current sensing device comprises:
an offset voltage supply circuit;
a noise filter;
a comparator configured to output a digital value corresponding to magnitude of the current flowing through the first shunt resistor; and
a second low-pass filter configured to output a signal having a preset second frequency or less.

15. The induction heating device of claim 10, wherein the controller is configured to determine an average value of the current values output from the first input current sensing device as the input current value of the first inverter and to determine an average value of the current values output from the second input current sensing device as the input current value of the second inverter.

16. The induction heating device of claim 10, wherein the controller is configured to determine the current value output from the first resonance current sensing device as the resonance current value of the first working coil and to determine the current value output from the second resonance current sensing device as the resonance current value of the second working coil.

17. An induction heating device comprising:
a working coil disposed to correspond to a heating area;
an inverter including a plurality of switching elements and configured to provide current to the working coil;
a rectifier circuit;
a smoothing circuit;
a drive circuit configured to provide a switching signal to each of the switching elements;
a controller configured to provide a control signal to the drive circuit for outputting the switching signal;
a shunt resistor to connect between the smoothing circuit and the inverter;
an input current sensing device configured to sense an input current value of the inverter based on the shunt resistor; and
a resonance current sensing device configured to sense a resonance current value of the working coil based on the shunt resistor.

18. The induction heating device of claim 17, wherein the input current sensing device is configured to sense the input current value of the inverter based on a current flowing through the shunt resistor.

19. The induction heating device of claim 17, wherein the resonance current sensing device is configured to sense the resonance current value of the working coil based on the current flowing through the shunt resistor.
